(19) United States
(12) Patent Application Publication
(10) Pub. No.: US 2010/0102457 A1
(43) Pub. Date: Apr. 29, 2010

(54) Hybrid Semiconductor Chip Package

(76) Inventors: Roden R. Topacio, Markham (CA); Yip Seng Low, Thornhill (CA); Liane Martinez, North York (CA); Andrew K.W. Leung, Markham (CA); Xiao Ling Shi, North York (CA)

Correspondence Address: TIMOTHY M HONEYCUTT ATTORNEY AT LAW, P O BOX 1577, CYPRESS, TX, 77410, US

(21) Appl. No.: 12/259,957

(22) Filed: Oct. 28, 2008

(51) Int. Cl. H01L 23/52; H01L 21/00

(52) U.S. Cl. 257/777; 438/127; 438/107; 257/E23.169

(57) ABSTRACT

Various apparatus and method of packaging semiconductor chips are disclosed. In one aspect, a method of manufacturing is provided that includes placing a semiconductor chip package into a mold. The semiconductor chip package includes a substrate that has a side and a first semiconductor chip coupled to the side in spaced apart relation to define a space between the first semiconductor chip and the side. A second semiconductor chip is mounted on the first semiconductor chip. At least one conductor wire is electrically coupled to the second semiconductor chip and the substrate. A molding material is introduced into the mold to flow into the space and establish an underfill and encapsulate the first semiconductor chip and the second semiconductor chip.

### BACKGROUND OF THE INVENTION

1. Field of the Invention

This invention relates generally to semiconductor processing, and more particularly to hybrid semiconductor chip packages and methods of making the same.

2. Description of the Related Art

As portable consumer products continue to evolve into designs of increasing complexity and capability, the integrated circuits that power them have had to keep pace. Many portable devices include one or more multi-chip packages, such as a stacked wire bond package. In some cases, cutting edge product designs call for a higher I/O density and more complicated application specific integrated circuit design than is provided with current stacked wire bond package configurations.

One recent advancement involves a so-called hybrid package. Unlike the conventional stacked wire bond package, the hybrid includes a flip-chip die mounted on a package substrate and a wire bond die mounted on the flip-chip die. Like virtually all flip-chip designs, the conventional hybrid requires an underfill material layer to be deposited in the space between the flip-chip die and the package substrate in order to lessen the unwanted effects of differences in coefficients of thermal expansion of the die, the solder joints, and the package substrate. In many process flows, the underfill material is deposited in a liquid state by way of capillary action. The underfill seldom remains confined to the die-to-substrate interface prior to thermal cure. Instead, the liquid runs out somewhat to form a berm surround the flip-chip die.

The underfill berm presents a no-go zone for any wire bond pads on the substrate. Accordingly, design rules must be written to ensure that substrate-based wire bond pads are placed sufficiently far away from the edges of the flip-chip die to avoid the no-go zone. Any attempt to shrink a package design or incorporate more I/O's will necessarily conflict with the requirement to keep the wire bond pads out of the underfill berm area.

The present invention is directed to overcoming or reducing the effects of one or more of the foregoing disadvantages.

### SUMMARY OF THE INVENTION

In accordance with one aspect of the present invention, a method of manufacturing is provided that includes placing a semiconductor chip package into a mold. The semiconductor chip package includes a substrate that has a side and a first semiconductor chip coupled to the side in spaced apart relation to define a space between the first semiconductor chip and the side. A second semiconductor chip is mounted on the first semiconductor chip. At least one conductor wire is electrically coupled to the second semiconductor chip and the substrate. A molding material is introduced into the mold to flow into the space and establish an underfill and encapsulate the first semiconductor chip and the second semiconductor chip.

In accordance with another aspect of the present invention, a method of manufacturing is provided that includes coupling a first semiconductor chip to a side of a substrate in spaced apart relation to define a space between the first semiconductor chip and the side and mounting a second semiconductor chip on the first semiconductor chip. At least one conductor wire is electrically coupled to the second semiconductor chip and the substrate. A molding material is placed on the substrate to encapsulate the first semiconductor chip and the second semiconductor chip so that a portion of the molding material is positioned in the space to provide an underfill.

In accordance with another aspect of the present invention, a semiconductor device is provided that includes a substrate that has a side and a first semiconductor chip coupled to the side in spaced apart relation to define a space between the first semiconductor chip and the side. A second semiconductor chip is mounted on the first semiconductor chip. At least one conductor wire is electrically coupled to the second semiconductor chip and the substrate. A molding encapsulates the first semiconductor chip and the second semiconductor chip such that a portion of the molding is positioned in the space to provide an underfill.

In accordance with another aspect of the present invention, an apparatus is provided that includes an electronic device and a semiconductor chip package coupled to the electronic device. The semiconductor chip package includes a substrate that has a side, a first semiconductor chip coupled to the side in spaced apart relation to define a space between the first semiconductor chip and the side, a second semiconductor chip mounted on the first semiconductor chip, at least one conductor wire electrically coupled to the second semiconductor chip and the substrate, and a molding encapsulating the first semiconductor chip and the second semiconductor chip. A portion of the molding is positioned in the space to provide an underfill.

### BRIEF DESCRIPTION OF THE DRAWINGS

The foregoing and other advantages of the invention will become apparent upon reading the following detailed description and upon reference to the drawings in which:

FIG. 1 is a partially exploded pictorial view of an exemplary conventional hybrid semiconductor chip package;

FIG. 2 is a sectional view of FIG. 1 taken at section 2-2;

FIG. 3 is a sectional view of an exemplary embodiment of a hybrid semiconductor chip package;

FIG. 4 is a magnified view of a portion of FIG. 3;

FIG. 5 is a magnified view of another portion of FIG. 3;

FIG. 6 is a magnified view of another portion of FIG. 3;

FIG. 7 is a sectional view of the exemplary hybrid semiconductor chip package undergoing a plasma cleaning;

FIG. 8 is a sectional view of the exemplary hybrid semiconductor chip package undergoing bond wire attachment;

FIG. 9 is a sectional view of the exemplary hybrid semiconductor chip package undergoing another plasma cleaning;

FIG. 10 is a sectional view of the exemplary hybrid semiconductor chip package undergoing a combined molding and underfill process; and

FIG. 11 is a pictorial view of the exemplary semiconductor chip package exploded from an exemplary electronic device.

### DETAILED DESCRIPTION OF SPECIFIC EMBODIMENTS

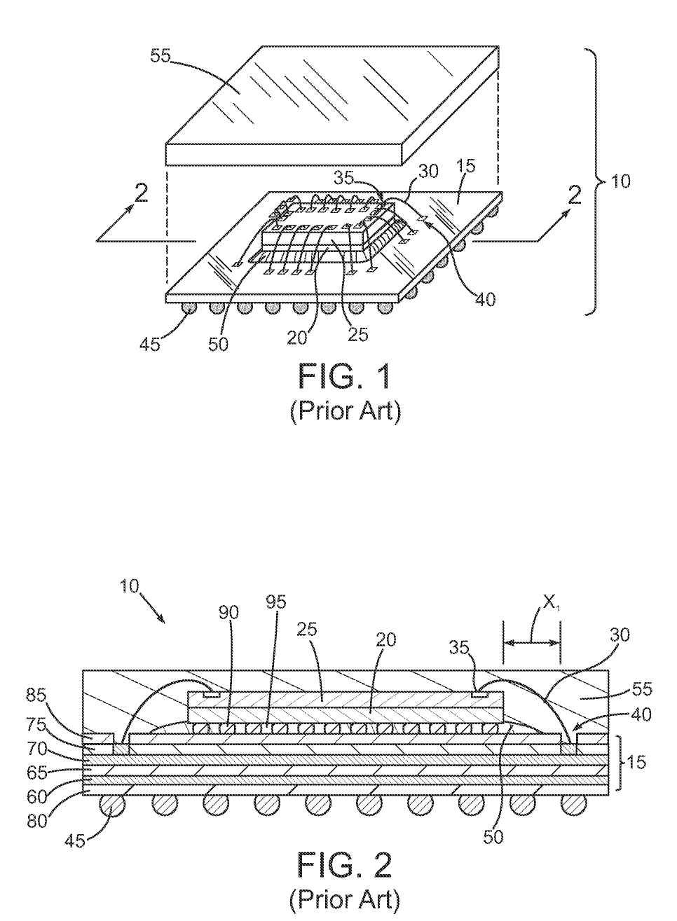

In the drawings described below, reference numerals are generally repeated where identical elements appear in more than one figure. Turning now to the drawings, and in particular to FIG. 1, therein is shown a partially exploded pictorial view of an exemplary conventional hybrid semiconductor chip package 10 (hereinafter hybrid package 10). The package 10 includes a base substrate 15 upon which a graphics processor semiconductor chip 20 and a memory semiconductor chip 25 are mounted in a stacked arrangement. The semiconductor chip 20 is flip-chip mounted and electrically interconnected to the substrate 15 by a plurality of solder joints which are not visible in FIG. 1. The semiconductor chip 25 is mounted on the chip 20 and electrically interconnect with the substrate 15 by way of a plurality of bond wires, one of which is labeled 30. Like the remaining bond wires, the bond wire 30 is electrically connected to the chip 25 at a bond pad 35 and to the substrate 15 at another bond pad 40. The substrate 15 is, in turn, provided with a ball grid array consisting of a plurality of solder balls 45 that are designed to mount on a landing area of another electronic device not shown. A capillary-deposited underfill is provided beneath and around somewhat the semiconductor chip 20. As described in more detail below in conjunction with FIG. 2, the requirement for the underfill 50 presents a geometric constraint on the configuration of the package 10. A mold 55 is shown exploded from the substrate 15. The depiction of the mold 55 as a separable structure from the package 15 is somewhat artificial and done for simplicity of illustration. In actual practice, the mold 55 is deposited as a flowing liquid over the substrate 15 and over the chips 20 and 25 and thereafter cures into a solid.

Additional details of the conventional package 10 may be understood by referring now to FIG. 2, which is a sectional view of FIG. 1 taken at section 2-2. Unlike FIG. 1, FIG. 2 shows the mold 55 in position and not exploded from the substrate 15. The substrate 15 is a laminate of four build-up layers 60, 65, 70 and 75 sandwiched between two solder masks 80 and 85. The build-up layers 60, 65, 70 and 75 consist of plural conductor traces interwoven with fiberglass insulating material. There are various bump and/or ball pads in the substrate 15 that are used to establish electrical contact with either the balls 45 or the solder joints 90 between the chip 20 and the substrate 15 that are not shown but will be shown in subsequent figures. Prior to the application of the mold 55, the underfill 50 is introduced in the space 95 between the chip 20 and the solder mask 85 by capillary action. Because capillary action is used, the underfill 50 will, of necessity, not remain confined to the space 95 but will spill out to essentially form a berm around the chip 20 as shown in FIGS. 1 and 2. As a consequence, the pad 40 for a given bond wire 30 must be positioned a minimum distance X₁ from the edge 100 of the chip 20 in order to ensure that the excess underfill 50 does not cover the bond pad 40 and thus prevent the attachment of the bond wire 30 thereto. This requirement for a minimum distance X₁ presents a constraint on the shrinkage of the package 10 in order to accommodate smaller device geometries and larger numbers of input/outputs between the chips 20 and 25 and the substrate 15.

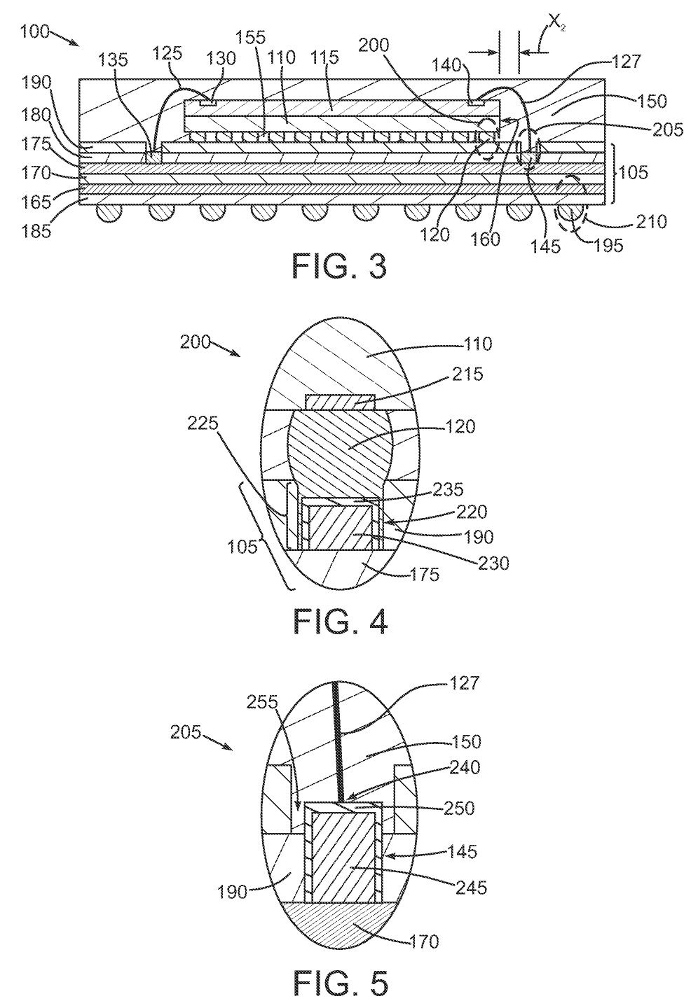

An exemplary embodiment of a new hybrid semiconductor chip package 100 may be understood by referring now to FIG. 3, which is a sectional view like FIG. 2. The package 100 includes a substrate 105 upon which a pair of semiconductor chips 110 and 115 are mounted. The semiconductor chips 110 and 115 may be graphics processors, microprocessors, combined graphics and microprocessors, memory devices, application specific integrated circuits or virtually any other type of integrated circuit. The semiconductor chip 110 is flip-chip mounted to the substrate 105 and electrically connected thereto by a plurality of solder joints 120. The number of solder joints 120 may be varied. The semiconductor chip 115 is mounted on the semiconductor chip 110 and electrically interconnected to the substrate 105 by way of a plurality of conductor wires or bond wires, two of which are shown and labeled 125 and 127. The number of bond wires 125 and 127 may be varied, but at least one should be used. The bond wire 127 is connected to the chip 115 at a bond pad 130 and to the substrate 105 at another bond pad 135. The bond wire 127 is similarly connected to the chip 115 by way of a bond pad 140 and to the substrate 105 by another bond pad 145. The bond wires 125 and 127 may be composed of gold, copper, aluminum, combinations of these or the like. Insulated gold wire may also be used. Metallurgical bonding between the bond wires 125 and 127 their respective pads 130, 135, 140 and 145 may be established by well-known ultrasonic or thermosonic excitation techniques.

A mold 150 encapsulates the chips 110 and 115 and the bond wires 125 and 127. However, and unlike the conventional design depicted in FIGS. 1 and 2, the mold in this illustrative embodiment not only encapsulates the chips 110 and 115 but also serves as an underfill in the space 155 between the chip 110 and the substrate 105. By using the mold 150 to additionally serve as an underfill, the problems associated with the conventional underfill 50 depicted in FIGS. 1 and 2 that require the minimum set off distance X₁ for the substrate-based wire bond pads such as the pad 40, are eliminated and thus, the pad 145 of the substrate 105 may be positioned much closer to the edge 160 of the chip 110 at say a distance X₂ where X₂<X₁.

The substrate 105 may consist of a build-up design as depicted in FIG. 3 that includes plural build-up layers 165, 170, 175 and 180 sandwiched between two solder masks 185 and 190. The design depicted in FIG. 3 may be termed a “1-2-1” design in which the layers 170 and 175 provide a central core and the layers 165 and 180 constitute build-ups from that central core. The number of layers in the substrate 105 may vary greatly depending upon the requirements of the chips 110 and 115. Each of the layers 165, 170, 175 and 180 may consist of plural conductor traces (not visible) that are interspersed with an insulating filler material such as fiberglass embedded epoxy. Electrical connections between two given layers, such as the layers 165 and 170, are provided by way of vias that are not visible in FIG. 3. A variety of material may be used for the conductor traces in the substrate 105, such as copper, gold, aluminum, combinations of these or the like. Optionally, the substrate 105 could be fabricated from other materials, such as ceramics, and be monolithic if desired.

In an exemplary embodiment, the conductor traces in the substrate 105 are composed of copper. The percentage of copper in a given layer of the substrate 105 may be tailored to yield acceptable substrate warpage and prevent moisture from penetrating into the package 100. Experiment has demonstrated that the combination of the inner layers 170 and 175 may have a copper density of about 30-50% by surface area with about 40% being preferred. The outer layers 165 and 180 may have a copper density of about 60-80% by surface area with about 70% being preferred. The desired copper density is achieved by tailoring the sizes and numbers of conductor structures consistent with electrical requirements.

The solder masks 185 and 190 may be fabricated using well-known application techniques, such as spin coating and thermal curing. A variety of polymer materials may be used. Two exemplary materials are PSR-4000 AUS703 manufactured by Taiyo Ink Mfg. Co., Ltd. or SR7000 manufactured by Hitachi Chemical Co., Ltd.

In order to interface the package 100 with another electronic device, the substrate 105 is provided with an external interconnect system. In this illustrative embodiment, the substrate 105 is provided with a ball grid array that includes a plurality of solder balls 195. However, other types of interconnect schemes, such as pin grid arrays, land grid arrays or other types of interconnects may be used if desired.

At this point, it will be useful to observe the locations of the dashed ovals 200, 205 and 210 in FIG. 3. The dashed oval 200 circumscribes portions of the semiconductor chip 110, one of the solder joints 120 and a portion of the substrate 105. The dashed oval 205 circumscribes a portion of the bond wire 127 and the pad 145, and the dashed oval 210 circumscribes a portion of the substrate 105 and one of the solder balls 195. The portions circumscribed by the dashed ovals 200, 205 and 210 will be shown at greater magnification in subsequent figures and described accordingly.

The portion of the package 100 circumscribed by the dashed oval 200 in FIG. 3 will now be described in conjunction with FIG. 4. As noted above, the plurality of solder joints establish electrical interconnects between the semiconductor chip 110 and the substrate 105. As an example of the plural joints, the solder joint 120 is ohmically connected to a bump pad 215 of the semiconductor chip 110 and to a conductor pad 220 formed in the substrate 105. It should be understood that the conductor pad 220 may be part of the overall interconnect or metallization layer associated with the top build-up layer 180 shown in FIG. 3. An opening 225 is formed in the solder mask 190 leading to the conductor pad 220 using well-known lithograhy and etching techniques. The conductor pad 220 may consist of a conductive core 230 that is coated with a plating layer 235. The core 230 may be composed of copper, gold, silver, aluminum, platinum, combinations of these or the like. In an exemplary embodiment, the core 230 may be composed of copper. The plating 235 may be composed of a nickel layer topped with a gold layer. The plating layer 235 may be formed on the conductor core 230 using a well-known plating process in which, prior to solder mask application, the conductor core 230 and the other conductor traces and pads co-planar with the core 230 are temporarily blanket coated with copper. Suitable lithographic masking is next applied to isolate the pad locations. Nickel and gold plating processes are next performed with the temporary blanket copper layer serving as a current path for the plating processes. Finally, the temporary blanket copper layer is etched away and the solder mask 190 is applied and lithographically patterned to yield the opening 225. The conductor pad 220 may have a rectangular or circular footprint. A rectangular footprint may enable tighter spacing of conductor traces.

Still referring to FIG. 4, the solder joint 120 may consist of a merger of a solder bump initially positioned on the bump pad 215 and a so-called pre-solder that is initially positioned on the pad 220, where the two are subsequently joined into a single joint 120 by way of a reflow process. The composition of the joint 120 may be varied greatly. An exemplary lead-based solder may have a composition at or near eutectic proportions, such as about 63% tin and 37% lead. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. It should be understood that one or more electrical interconnects or traces (not visible) may be coupled to the bump pad 220 in the substrate 105 that are designed to electrically interconnect the pad 220 with other structures in the substrate 105, such as any of the ball grid array balls 195 depicted in FIG. 3. The bump pad 215 may be composed of the same types of materials as the conductor pad 220.

Attention is now turned to FIG. 5, which is a magnified view of the portion of FIG. 3 circumscribed by the dashed oval 205. The bond wire 127 is electrically connected to the pad 145 at the location 240 by way of an ultrasonic or thermosonic excitation process. The pad 145 may consist of a conducting core 245 coated with a nickel gold plating that may be substantially identical to the plating layer 235 depicted in FIG. 4 described above. An opening 255 in the solder mask 190 is made using well-known lithographic techniques to enable the bond wire 127 to be secured to the pad 145. The opening 255 is subsequently filled by the mold 150 during the molding process. Note that just a small portion of the build-up layer 175 is visible in FIG. 5.

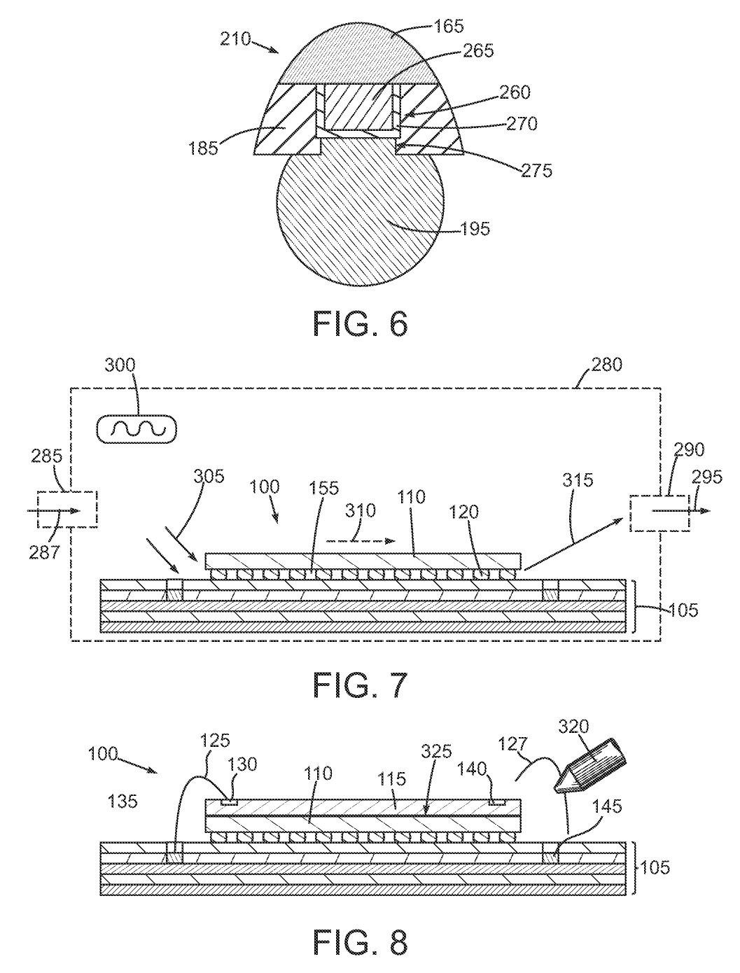

Attention is now turned to FIG. 6, which is a magnified view of the portion of FIG. 3 circumscribed by the dashed oval 210. The solder ball 195 is metallurgically bonded to a ball pad 260 that may consist of a conducting core 265 and a plating layer 270 fabricated as generally described above in connection with the pad 145 depicted in FIG. 5. An opening 275 in the solder mask 185 is established by well-known lithographic techniques to enable the solder ball 195 to be reflowed and bond with the pad 260. The ball 195 may have the same composition as the joint 120 depicted in FIGS. 3 and 4. It should be understood that the processing of the pad 260 and the pad 145 on the opposite side shown in FIGS. 3 and 4 may be conducted at the same time.

An exemplary process flow for assembling the hybrid package 100 may be understood by referring now to FIGS. 7, 8, 9 and 10 and initially to FIG. 7. At this stage, the package 100 is partially assembled up to the point where the semiconductor chip 110 is flip-chip mounted to the substrate 105 and a reflow process has been performed to establish the plural solder joints 120. To ensure that the mold 150 depicted in FIG. 3, reliably penetrates uniformly into the space 155 between the chip 110 and the substrate 105, a plasma clean process is performed. The package 100 is placed in a plasma chamber 280 that includes an inlet 285 to receive a gas 287 or gases suitable for the plasma treatment process and an outlet 290 that is connected to a vacuum source (not shown) to actively draw cleaning products 295 from the chamber 280. The plasma chamber 280 includes an excitation source 300 that may be an RF source, a microwave source or other type of plasma excitation source as desired. Once the plasma is excited, it is desirable for the constituents of the plasma to impinge the substrate 105 at an angle as suggested by the arrows 305 so that a cleansing effect will be provided for the space 155 between the chip 110 and the substrate 105. It is desirable for plasma to proceed along the space 155 in the direction of the dashed arrow 310 and then exit toward the outlet 290 as suggested by the arrow 315. A variety of plasma chemistries and parameters may be used. In an exemplary embodiment, the following recipe may be used.

TABLE 1

| | |
|---|---|
| Atmosphere | Argon 5.0 sccm |
| | O₂ 2.0 sccm |
| Excitation Source | RF |
| Excitation Power | 700 W |
| Time | 10.0 minutes |

Referring now to FIG. 8, subsequent to the initial plasma treatment, the package 100 may be fitted with the plural bond wires 125 and 127b by way of a pick and place mechanism 320 or other device as desired. Well-known ultrasonic or thermosonic excitation may be used in order to establish the metallurgical bonds between the bond wires 125 and 127 and the pads 130, 135, 140 and 145 of the chip 110 and substrate 105. Prior to the wire bonding, the semiconductor chip 115 is mounted to the semiconductor chip 110 by way of an adhesive, such as an epoxy, which may be applied at the interface 325 between the two chips 110 and 115.

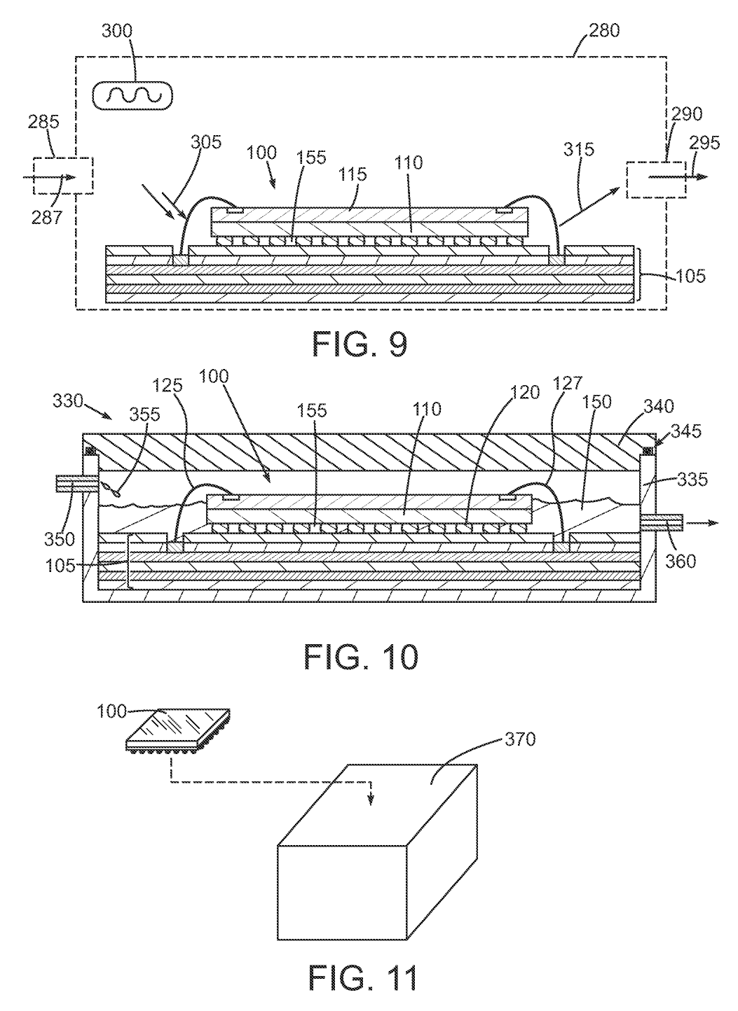

Following the wire bonding and mounting of the semiconductor chip 115, the package 100 is returned to the plasma chamber 280 as shown in FIG. 9 and another plasma clean process is performed. In this embodiment, an atmosphere 287 may be introduced into the inlet 285, converted to plasma and the end products 295 may be drawn from the outlet 290 as described above and suggested by the arrow 315. In an exemplary embodiment, the following recipe may be used.

TABLE 2

| | |
|---|---|
| Atmosphere | Argon 2000 sccm |
| | O₂ 240 sccm |
| Excitation Source | Microwave |
| Excitation Power | 800 W |
| Time | 5.0 minutes |

As with the first plasma cleaning step, the goal is to ensure an angular impingement 305 so that an adequate supply of cleansing particles translates across the space 155 between the chip 110 and the substrate 105.

Following the plasma clean, the package 100 is ready to receive the mold 150. In this regard, and as shown in FIG. 10, the package 100 may be inserted into a mold 330 that consists of a chamber 335 sealed with an upper lid 340. The lid 340 may be sealed to the chamber 335 by way of an O-ring 345 or other seal as desired. An inlet 350 is provided in the chamber 335 to enable the introduction of liquified mold material 355 that will settle on the substrate 105 and encapsulate the chips 110 and 115 and ultimately solidify into the mold 150. The molding material need completely encapsulate the semiconductor chips 110, 115 or the bond wires 125 and 127. An outlet 360 is provided in the chamber 355 and connected to a vacuum source so that the liquid mold material 355 may be rapidly drawn into the chamber 335 and sucked into the space 155 between the chip 110 and substrate 105. It may be useful to position the inlet 350 and the outlet vertically relatively close to the vertical position of the space 155 to ensure that the mold of the liquid material 355 is readily drawn through the space 155. After all, the mold 155 is designed to function not only as a mold in the traditional sense but also as an underfill material.

The material selected for the mold 150 should exhibit properties that favor the dual-use nature, that is, mold and underfill, called for in this illustrative embodiment. It is desirable for the mold material to exhibit a suitable viscosity at the molding temperature and filler size that facilitate uniform invasion of the space 155. In addition, the molding material should have a molding temperature that is lower than the melting point of the solder joints 120 so that the solder is not compromised during molding. In an exemplary embodiment, the mold material may have a viscosity of about 9.0 Pa-s, a molding temperature of about 165° C. and a maximum filler particle size of about 30.0 μm. Two commercial variants are Nitto's GE100 and Matsushita's X8715.

After the molding process, the package 100 may be removed from the chamber 335 and the solder balls depicted in FIG. 3 may be secured thereto using a well-known reflow processes. The package 100 may thereafter be inserted into an electronic device. It should be understood that the package 100 may be processed individually or as part of a larger grouping, such as a strip, that is ultimately singulated.

The package 100 may be used in a myriad of different electronic devices. An exemplary electronic device, shown in FIG. 11, may be a computer, a digital television, a handheld mobile device, a server, a memory device, an add-in board such as a graphics card, or any other computing device employing semiconductors.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
placing a semiconductor chip package into a mold, the semiconductor chip package including a substrate having a side, a first semiconductor chip coupled to the side in spaced apart relation to define a space between the first semiconductor chip and the side, a second semiconductor chip mounted on the first semiconductor chip, and at least one conductor wire electrically coupled to the second semiconductor chip and the substrate; and
introducing a molding material into the mold to flow into the space and establish an underfill and encapsulate the first semiconductor chip and the second semiconductor chip.

2. The method of claim 1, comprising forming a plurality of solder joints in the space that electrical couple the first semiconductor chip to the substrate.

3. The method of claim 1, wherein the introducing the molding material comprises connecting a vacuum to the mold to draw the molding material through the space.

4. The method of claim 1, wherein the molding material encapsulates the at least one conductor wire.

5. The method of claim 1, comprising electrically coupling the semiconductor chip package to an electronic device.

6. The method of claim 1, comprising plasma cleaning the semiconductor chip package in a plasma chamber operable to draw plasma constituents through the space during the cleaning.

7. A method of manufacturing, comprising:
coupling a first semiconductor chip to a side of a substrate in spaced apart relation to define a space between the first semiconductor chip and the side;
mounting a second semiconductor chip on the first semiconductor chip;
electrically coupling at least one conductor wire to the second semiconductor chip and the substrate; and
placing a molding material on the substrate to encapsulate the first semiconductor chip and the second semiconductor chip so that a portion of the molding material is positioned in the space to provide an underfill.

8. The method of claim 7, wherein the coupling the first semiconductor chip comprises forming a plurality of solder joints in the space that electrical couple the first semiconductor chip to the substrate.

9. The method of claim 7, wherein the placing the molding material comprises positioning the substrate, the first semiconductor chip and the second semiconductor chip in a mold and introducing the molding material into the mold.

10. The method of claim 9, comprising connecting a vacuum to the mold to draw the molding material through the space.

11. The method of claim 7, wherein the molding material encapsulates the at least one conductor wire.

12. The method of claim 7, comprising electrically coupling the semiconductor chip package to an electronic device.

13. The method of claim 7, comprising plasma cleaning the semiconductor chip package in a plasma chamber operable to draw plasma constituents through the space during the cleaning.

14. A semiconductor device, comprising:
a substrate having a side;
a first semiconductor chip coupled to the side in spaced apart relation to define a space between the first semiconductor chip and the side;
a second semiconductor chip mounted on the first semiconductor chip;
at least one conductor wire electrically coupled to the second semiconductor chip and the substrate; and
a molding encapsulating the first semiconductor chip and the second semiconductor chip, a portion of the molding being positioned in the space to provide an underfill.

15. The apparatus of claim 14, wherein the first semiconductor chip comprises a processor.

16. The apparatus of claim 15, wherein the second semiconductor chip comprises a memory device.

17. An apparatus, comprising:
an electronic device; and
a semiconductor chip package coupled to the electronic device, the semiconductor chip package including a substrate having a side, a first semiconductor chip coupled to the side in spaced apart relation to define a space between the first semiconductor chip and the side, a second semiconductor chip mounted on the first semiconductor chip, at least one conductor wire electrically coupled to the second semiconductor chip and the substrate, and a molding encapsulating the first semiconductor chip and the second semiconductor chip, a portion of the molding being positioned in the space to provide an underfill.

18. The apparatus of claim 17, wherein the first semiconductor chip comprises a processor.

19. The apparatus of claim 18, wherein the second semiconductor chip comprises a memory device.

20. The apparatus of claim 17, wherein the electronic device comprises a handheld mobile device.
